(19) United States
(12) Patent Application Publication
(10) Pub. No.: US 2014/0124126 A1
(43) Pub. Date: May 8, 2014

(54) DEVICE AND METHOD FOR MANUFACTURING DONOR SUBSTRATE

(71) Applicant: SAMSUNG DISPLAY CO., LTD., Yongin-City (KR)

(72) Inventors: Hyo-Yeon Kim, Yongin-City (KR); Ha-Jin Song, Yongin-City (KR); Byeong-Wook Yoo, Yongin-City (KR); Sang-Woo Pyo, Yongin-City (KR); Kwan-Hee Lee, Yongin-City (KR); Hye-Yeon Shim, Yongin-City (KR); Ji-Young Kwon, Yongin-City (KR)

(73) Assignee: SAMSUNG DISPLAY CO., LTD., Yongin-City (KR)

(21) Appl. No.: 13/916,449

(22) Filed: Jun. 12, 2013

(30) Foreign Application Priority Data
Nov. 7, 2012 (KR) 10-2012-0125643

(51) Int. Cl. H01L 51/56

(52) U.S. Cl. CPC H01L 51/56
USPC 156/163; 156/543; 156/60; 156/250

(57) ABSTRACT

A device for manufacturing a donor substrate, the device including a film supply unit for supplying a flexible base film in a supply direction, a film guide unit at a front of the film supply unit in the supply direction for supporting the base film and for guiding the base film in the supply direction, a frame transferring unit at the front of the supply direction and for providing a support frame configured to be coupled to the base film and for transferring the frame while contacting a first side of the base film, and a heating unit facing the frame transferring unit with the base film therebetween for heating and for pressurizing a part of the base film contacting the support frame.

### CROSS-REFERENCE TO RELATED APPLICATION

This application claims priority to and the benefit of Korean Patent Application No. 10-2012-0125643 filed in the Korean Intellectual Property Office on Nov. 7, 2012, the entire content of which is incorporated herein by reference.

### BACKGROUND

1. Field

Embodiments of the present invention relate generally to a device and method for manufacturing a donor substrate.

2. Description of the Related Art

An organic light emitting diode (OLED) display is a self-emission display device in which holes injected from an anode and electrons injected from a cathode combine with each other in the organic emission layer to emit light. Further, since the organic light emitting diode display has desirable characteristics such as low power consumption, high luminance, a wide viewing angle, and a high response speed, the organic light emitting diode display receives attention as a next-generation display device for portable electronic devices.

The organic light emitting diode (OLED) display includes an anode, a cathode, and organic films between the anode and the cathode. The organic films include an emission layer, and can further include a hole injection layer (HIL), a hole transport layer (HTL), an electron transport layer (ETL), and an electron injection layer (EIL). An organic electric field light emitting element is classified as a polymer organic electric field light emitting element, or a small molecular organic electric field light emitting element, depending on a material that forms the organic film (e.g., the emission layer).

The emission layer is typically patterned, and a method for patterning the emission layer includes using a fine metal mask in the case of the small molecular organic electric field light emitting element, and an ink-jet printing or laser induced thermal imaging (LITI) method in the case of the polymer organic electric field light emitting element. The laser induced thermal imaging method uses a mask pattern for patterning laser beams that are generated by a laser beam generator, and irradiating the patterned laser beams on a donor substrate including a transfer layer to transfer a part of the transfer layer to the organic light emitting diode (OLED) display to form an emission layer thereon, so it has advantages of finely, or precisely, patterning the organic film, being applicable to a wide area, and being suitable for high resolution.

When the organic film is formed using the laser induced thermal imaging (LITI) method, a light source, an acceptor substrate (e.g., an organic light emitting element substrate), and a donor substrate are needed. The donor substrate is configured with a base film, a light-to-heat conversion (LTHC) layer, and a transfer layer. Light that is output by the light source is absorbed into the light-to-heat conversion layer of the donor substrate to be converted into heat energy, and the converted heat energy changes an adhesion force between the LTHC layer, the transfer layer, and the acceptor substrate so that a material of the transfer layer formed on the donor substrate is transferred to the acceptor substrate, and the organic emission layer is patterned on the acceptor substrate.

In related art, the base film on which the LTHC layer is formed is manually cut to a predetermined size using a cutting device, the cut base film is extended and fixed to the frame using a tape or an adhesive, and a transfer layer is formed on the base film that is fixed to the frame, thereby forming the donor substrate. The donor substrate on which the transfer layer is formed is arranged on the acceptor substrate in a vacuous state to thus transfer the transfer layer on the donor substrate to the acceptor substrate by the laser induced thermal imaging (LITI) method.

When the donor substrate is manufactured, the process for extending the base film and fixing it to the frame is manually performed so that the base film is not typically extended in a uniform manner, so that wrinkles may occur on the base film, and the degree to which the base film is extended for each manufactured donor substrate may not be uniform.

The above information disclosed in this Background section is only for enhancement of understanding of the background of the described technology and therefore it may contain information that does not form the prior art that is already known in this country to a person of ordinary skill in the art.

### SUMMARY

Embodiments of the present invention provide a device and method for manufacturing a donor substrate for reducing or preventing wrinkles by extending a base film in a more uniform manner.

Embodiments of the present invention provide a manufacturing device and method for maintaining an extended degree of a base film of a manufactured donor substrate.

An exemplary embodiment of the present invention provides a device for manufacturing a donor substrate, the device including a film supply unit for supplying a flexible base film in a supply direction, a film guide unit at a front of the film supply unit in the supply direction for supporting the base film and for guiding the base film in the supply direction, a frame transferring unit at the front of the supply direction and for providing a support frame configured to be coupled to the base film and for transferring the frame while contacting a first side of the base film, and a heating unit facing the frame transferring unit with the base film therebetween for heating and for pressurizing a part of the base film contacting the support frame.

The heating unit may have a shape that corresponds to the support frame.

The heating unit may be movable to contact a second side of the base film.

The film supply unit may include a roller and may be configured to unwind the base film wound on the roller.

The device may further include an extension tray at the front of the film supply unit in the supply direction, and for contacting the first side of the base film and for stretching the base film in a stretching direction.

The device may further include a supplementary guide unit at the front of the film supply unit in the supply direction and for supporting the base film in a crossing direction crossing the supply direction.

The supplementary guide unit may be movable in the crossing direction.

Another exemplary embodiment of the present invention provides a method for manufacturing a donor substrate, including supplying a flexible base film in a supply direction, contacting a first side of the base film with a support frame for supporting the base film, and heating a part of the base film contacting the support frame to adhere the support frame to the base film.

The adhering of the support frame to the base film may include heating a second side of the base film.

The heating of the part of the base film contacting the support frame may include providing a heating unit having a shape that corresponds to the support frame.

The supplying of the base film in the supply direction may include extending the base film in the supply direction.

The supplying of the base film in the supply direction may include extending the base film in a crossing direction crossing the supply direction.

The supplying of the base film in the supply direction may include unwinding the base film, and continuously supplying the base film in the supply direction, the supply direction being a direction in which the base film is unwound.

The method may further include separating an area of the base film to which the support frame is attached from the supplied base film by cutting the base film after the attaching of the support frame to the base film.

The method may further include extending the base film in a stretching direction crossing the supply direction, before the contacting the first side of the base film with the support frame.

According to embodiments of the present invention, the donor substrate for more uniformly extending the base film and for reducing or preventing wrinkles is manufactured. Further, the extended degree of the base film for each donor substrate is maintained.

Hence, an inferiority/failure rate of the manufactured donor substrate is reduced, and a fine air gap that may occur between the donor substrate and the acceptor substrate in the transfer process is reduced to increase transfer efficiency. In addition, the donor substrate can be manufactured through the disclosed process and device to reduce production costs of the donor substrate, reduce the manufacturing time, and easily manufacture a wide donor substrate.

### BRIEF DESCRIPTION OF THE DRAWINGS

FIG. 1A and FIG. 1B show perspective views of a device for manufacturing a donor substrate according to an exemplary embodiment of the present invention.

FIG. 2 shows a flowchart of a method for manufacturing a donor substrate according to an exemplary embodiment of the present invention.

FIG. 3 to FIG. 8 sequentially show a method for manufacturing a donor substrate according to an exemplary embodiment of the present invention.

FIG. 9 shows a perspective view of a donor substrate manufactured by a device and method for manufacturing a donor substrate according to an exemplary embodiment of the present invention.

FIG. 10A to FIG. 10C show a process for manufacturing an organic light emitting diode (OLED) display by using a donor substrate that is manufactured by a device and method for manufacturing a donor substrate according to an exemplary embodiment of the present invention.

### DETAILED DESCRIPTION

A device and method for manufacturing a donor substrate according to an embodiment of the present invention will now be described with reference to the accompanying drawings. As those skilled in the art would realize, the described exemplary embodiments may be modified in various different ways, all without departing from the spirit or scope of the present invention. On the contrary, exemplary embodiments introduced herein are provided to make disclosed contents thorough and complete, and to sufficiently transfer the spirit of the present invention to those skilled in the art. Like reference numerals designate like elements throughout the drawings.

In the drawings, the thickness of layers, films, panels, regions, etc., may be exaggerated for clarity and for better understanding and ease of description. It will be understood that when an element such as a layer, film, region, or substrate is referred to as being “on” another element, it can be directly on the other element, or one or more intervening elements may be present.

In addition, unless explicitly described to the contrary, the word “comprise” and variations such as “comprises” or “comprising” will be understood to imply the inclusion of stated elements, but not the exclusion of any other elements. Throughout this specification, the word “on” will be understood to be positioned above or below a target portion, and will not necessarily be understood to refer to an upper side based on a gravity direction.

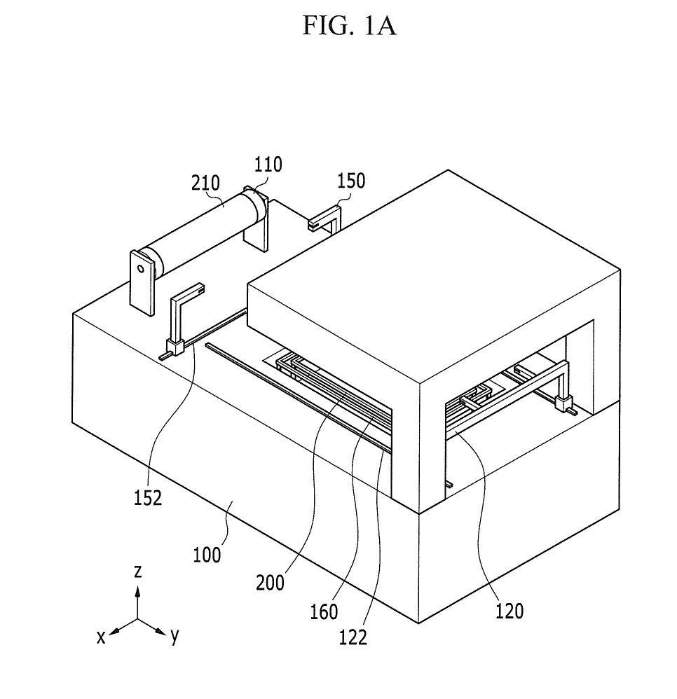

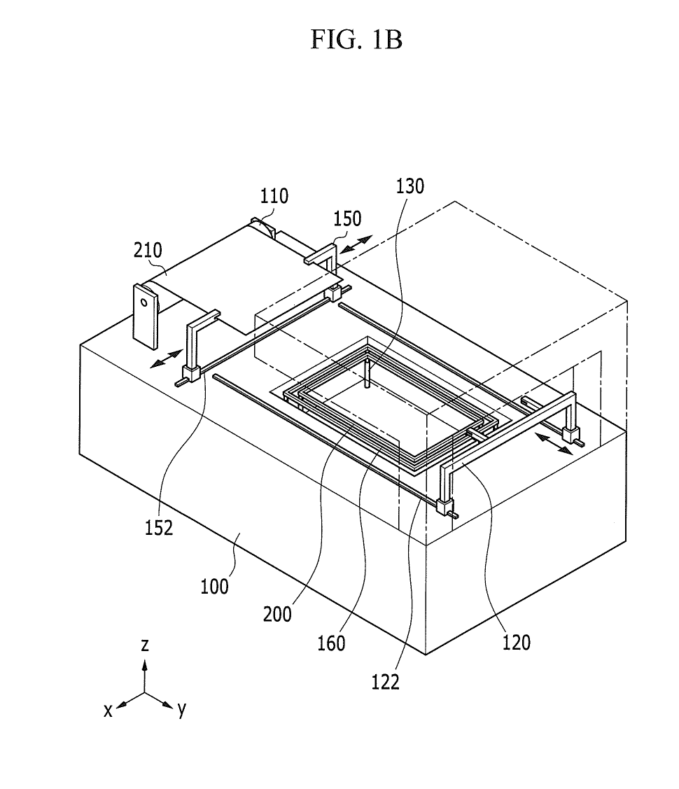

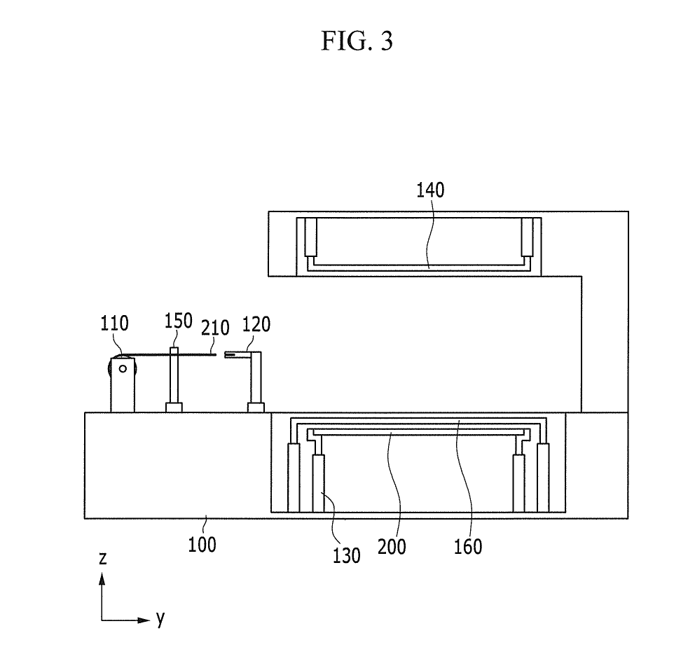

FIG. 1A and FIG. 1B show perspective views of a device for manufacturing a donor substrate according to an exemplary embodiment of the present invention. Referring to FIG. 1A and FIG. 1B, the device for manufacturing a donor substrate includes a film supply unit 110, a film guide unit 120, a frame transferring unit 130, a heating unit 140 (see FIGS. 3 to 8), and a body unit 100 that supports the constituent elements.

The film supply unit 110 is located on a first side of the body unit 100 to supply a base film 210 in a first direction/supply direction (e.g., the y-axis direction of the figures). The base film 210 supports a light-to-heat conversion layer for absorbing light and converting it into heat energy, and a transfer layer made of a material to be patterned. The light-to-heat conversion layer can be provided on the base film 210.

To reduce or prevent generation of cracks and particles in the transfer layer, the transfer layer can be formed after a support frame 200 is attached to the base film 210. When the base film 210 is flexible, it can be wound and then provided to the roller-type film supply unit 110, enabling the base film 210 to be continuously provided by unwinding the base film 210 that is wound on the roller and by providing the same in the first direction.

The film guide unit 120 is located on a first side of the film supply unit 110, supports the base film 210 in front of the supply direction of the base film 210, and guides the base film 210 in the supply direction. The film guide unit 120 holds an end of the base film 210 and guides it in the supply direction so that the base film 210 may be spread on a first surface of the body unit 100. As shown in FIG. 1B, the film guide unit 120 is formed to shift along a guide rail 122 that is formed on the first surface of the body unit 100, although the present invention is not restricted to this configuration, and many other configurations for moving the film guide unit 120 in the first direction are possible.

A supplementary guide unit 150 is located in a forward part of the supply direction of the base film 210. The supplementary guide unit 150 supports the base film 210 in a second direction/crossing direction (e.g., x-axis direction of FIGS. 1A and 1B) crossing the supply direction of the base film 210 to reduce or prevent wrinkles on the base film 210. The supplementary guide unit 150 is formed as a pair of components so that it may move in the crossing direction, and the base film 210 is taken at both sides of the crossing direction and is then pulled to the outer part of the base film 210. The supplementary guide unit 150 is formed to move along the guide rail 152 that is formed on one surface of the body unit 100, although the present invention is not restricted to this configuration, and many other configurations for moving the supplementary guide unit 150 in the crossing direction are possible.

The frame transferring unit 130 provides a support frame 200 to the base film 210, and controls the support frame 200 to contact one surface of the base film 210. The frame transferring unit 130 is located in a forward part of the first direction in which the base film 210 is supplied.

The support frame 200 is a member for tightly extending and supporting the base film 210, has an opening in the center, is formed to be polygonal having a plurality of sides, and in general, as shown in FIG. 1B, may be formed to have a rectangular shape. The support frame 200 extends and supports the base film 210 so that, in the subsequent heat transfer process, it can reduce a fine air gap that may occur between the donor substrate and the acceptor substrate. In the present exemplary embodiment, the support frame 200 is attached to one side of the base film 210. The portion of the support frame 200 that contacts the base film 210 forms a flat surface so it can be attached to one side of the base film 210 without distortion. When a light-to-heat conversion layer is provided on one side of the base film 210, the support frame 200 is attached to another side thereof.

The frame transferring unit 130 holds the support frame 200, and when the base film 210 is located in the support frame 130, the support frame 200 is transferred such that the support frame 200 may contact one side of the base film 210. For the support frame 200 to contact and extend (e.g., stretch, or pull) the base film 210, the frame transferring unit 130 may transfer the support frame 200 in a vertical direction (e.g., z-axis direction of the figures) of the base film 210. When the base film 210 is horizontally spread, the frame transferring unit 130 can provide the support frame 200 at the bottom of one side of the base film 210. In embodiments of the present invention, the frame transferring unit 130 can be driven according to a hydraulic cylinder method, although various other methods for transferring the support frame 200 in the top or bottom direction are possible.

An extension tray 160 can be located in front of the supply direction of the base film 210. Before attaching the support frame 200 to the base film 210, the extension tray 160 extends the base film 210 in the vertical direction so as to reduce or prevent wrinkling of the base film 210. When the base film 210 is horizontally extended, the extension tray 160 can be located on the bottom of the base film 210. Like the frame transferring unit 130, the extension tray 160 can select from various methods for moving back and forth in the vertical direction.

The extension tray 160 is formed to correspond to the support frame 200, and may be a little larger than the support frame 200. As shown in FIG. 1B, when the support frame 200 is formed to have a rectangular shape, the extension tray 160 is formed to have a rectangular shape that is larger than the support frame 200, and to surround the support frame 200. When the extension tray 160 is formed as described above, the inside of the extension tray 160 with the rectangular shape causes the base film 210 to become taut, so when the support frame 200 is attached to the base film 210, so that the wrinkles of the base film 210 can be efficiently reduced or prevented.

The base film 210 is extended in the supply direction (x-axis direction) by the film guide unit 120, the crossing direction (y-axis direction) crossing the supply direction by the supplementary guide unit 150, and the vertical direction (z-axis direction) of one side of the base film 210 so that the base film 210 is spread with few or no wrinkles.

The heating unit 140 heats and pressurizes the part of the base film 210 contacting the support frame 200 to bond the support frame 200 to the base film 210, and may apply heat to the base film 210 to thermally transform the base film 210 so that the support frame 200 may be attached to the base film 210. The heating unit 140 is arranged or oriented to face the frame transferring unit 130 with the base film 210 therebetween. When the support frame 200 is provided at the bottom of one side of the base film 210, the heating unit 140 is located at the top of one side of the base film 210. In the present embodiment, the heating unit 140 can select one of various methods for vertically moving back and forth on one side of the base film 210.

The heating unit 140 heats and pressurizes the part of the base film 210 contacting the support frame 200, and therefore may be formed to have a shape and size that correspond to the support frame 200. For example, when the support frame 200 is formed to have a rectangular shape with four sides, the heating unit 140 can be formed to have a rectangular shape in a like manner.

An operation of a device for manufacturing a donor substrate according to an exemplary embodiment of the present invention, and a method for manufacturing a donor substrate will now be described with reference to drawings.

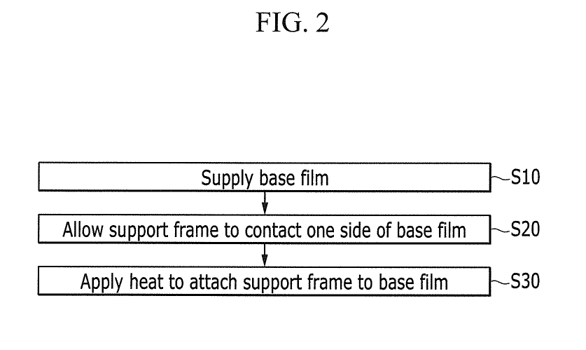

FIG. 2 shows a flowchart of a method for manufacturing a donor substrate according to an exemplary embodiment, and FIGS. 3 to 8 sequentially show a method for manufacturing a donor substrate according to an exemplary embodiment.

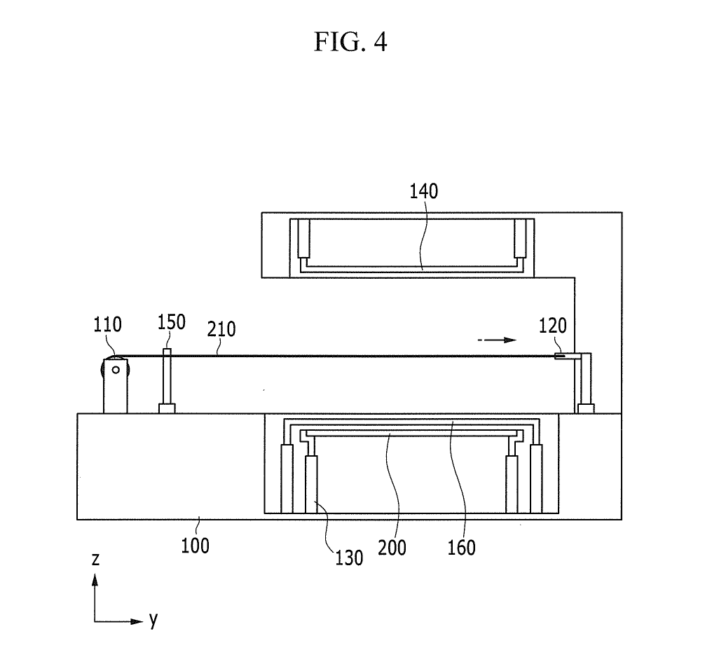

A flexible base film 210 is supplied in a first direction (y-axis direction) (S10). As shown in FIG. 3, the base film 210 is wound on the film supply unit 110 including a roller, and can be unwound and continuously supplied in the first direction. When the base film 210 is supplied, both sides of the base film 210 are held by the supplementary guide unit 150 (refer to FIG. 1B) to extend (e.g., stretch, pull, or spread) the base film 210 in the crossing direction (x-axis direction). As shown in FIG. 4, with reference to the supply direction, an end of the base film 210 is held by the film guide unit 120 and the base film 210 is spread (e.g., stretched) in the supply direction. In the present embodiment, the roller of the film supply unit 110 may be unwound and the rate of supplying the base film 210 may be slower than the rate for the film guide unit 120 to transfer the base film 210 so that the base film 210 may be extended, pulled, or stretched and provided in the supply direction.

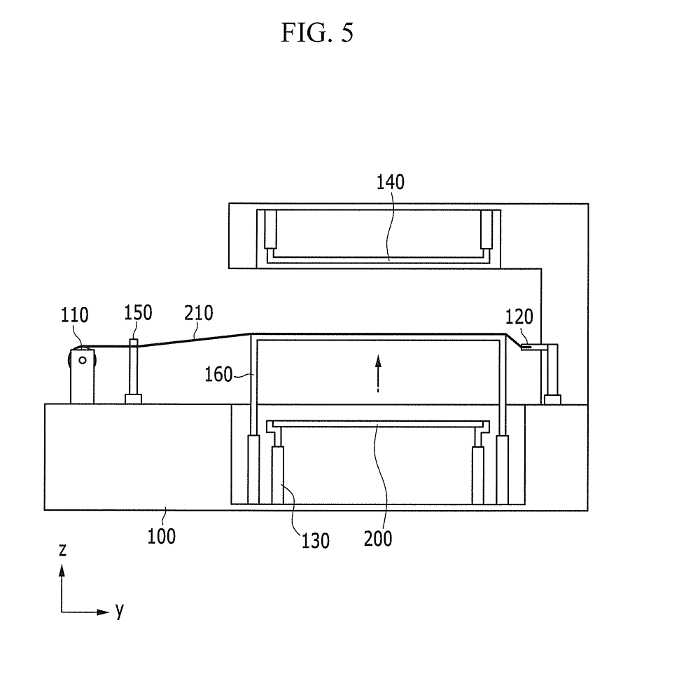

The support frame 200 for supporting the base film 210 is allowed to contact one side of the base film 210 (S20). In the present embodiment, the base film 210 can be extended (e.g., stretched) in the vertical direction (e.g., a stretching direction, or the z-axis direction of FIGS. 1A and 1B), and as shown in FIG. 5, the base film 210 is extended by lifting the extension tray 160 that is located below the spread base film 210.

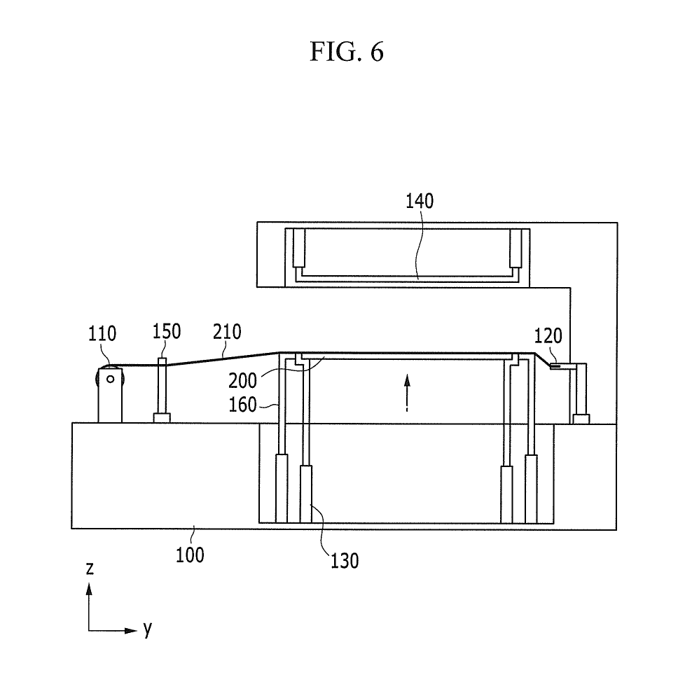

As shown in FIG. 6, the support frame 200 contacts the bottom of the base film 210 by lifting the frame transferring unit 130 that is located below the spread base film 210. The support frame 200 can contact the base film 210 while the base film 210 is extended in the vertical direction by the extension tray 160. When the extension tray 160 and the support frame 200 are respectively formed to have a rectangular shape, the support frame 200 is provided inside the rectangular extension tray 160 (refer to FIG. 1B).

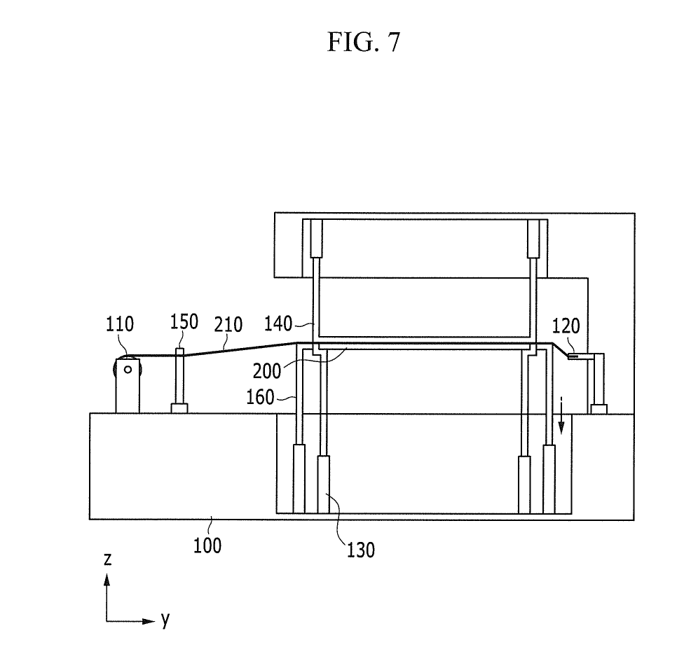

The part of the base film 210 contacting the support frame 200 is heated to attach the support frame 200 to the base film 210 (S30). As shown in FIG. 7, one side of the base film 210 that is opposite the side to which the support frame 200 is attached is pressurized and heated.

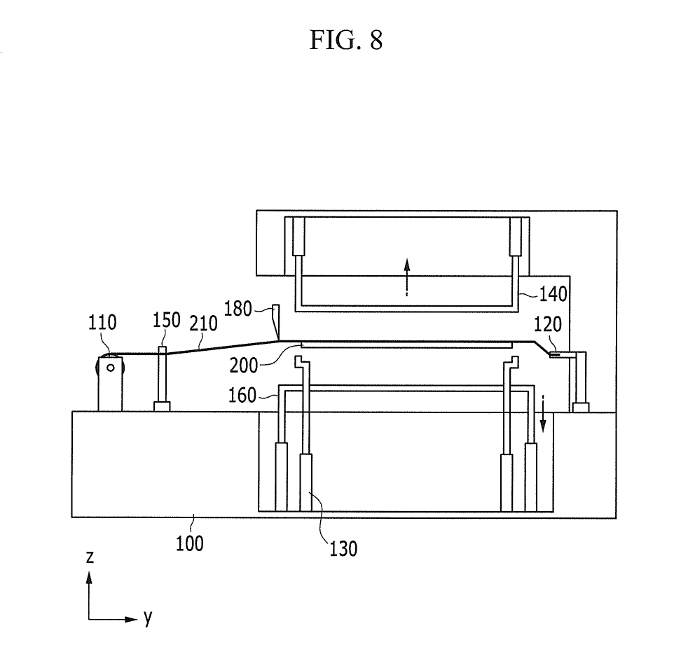

The heating unit 140 is formed to have the same shape and size as the support frame 200, and heats the part of the base film 210 contacting the support frame 200. The base film 210 at the heated part is thermally transformed and is adhered to the support frame 200. As shown in FIG. 8, after heating, the heating unit 140 is detached from the base film 210. When the heating unit 140 contacts the base film 210 for too long, thermal distortion of the base film 210 may be increased and the base film 210 can be wrinkled.

When the support frame 200 is attached to the base film 210, the base film 210 is cut using a cutting device 180 to thus separate the base film area to which the support frame 200 is attached from the rest of the supplied base film 210. The frame transferring unit 130 and the extension tray 160 are returned to their original positions and are prepared for the above-noted process.

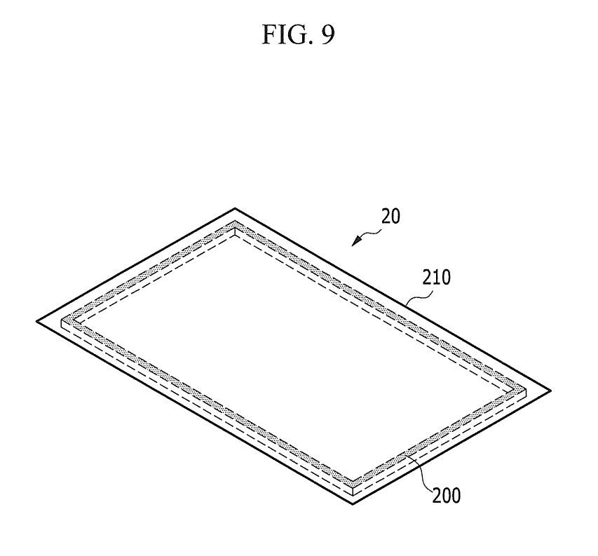

FIG. 9 shows a perspective view of a donor substrate manufactured by a device and method for manufacturing a donor substrate according to an exemplary embodiment.

The support frame 200 is attached to one side of the base film 210 according to the manufacturing process. A light-to-heat conversion layer can be formed on another side of the base film 210 to which the support frame 200 is not attached. A transfer layer may be formed on the light-to-heat conversion layer to finish the donor substrate. The transfer layer may be formed by using a general coating method such as, for example, extrusion, spin coating, knife coating, or vacuum deposition. The donor substrate 20 can further include a plurality of layers having various functions such as a buffer layer, as well as the base film 210, the light-to-heat conversion layer, and the transfer layer.

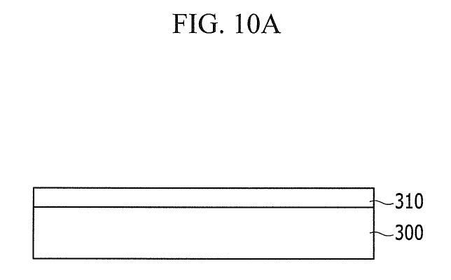

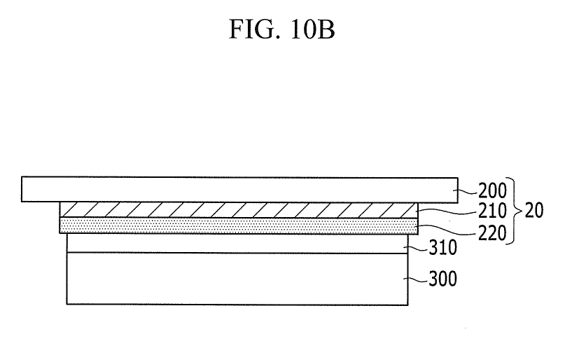

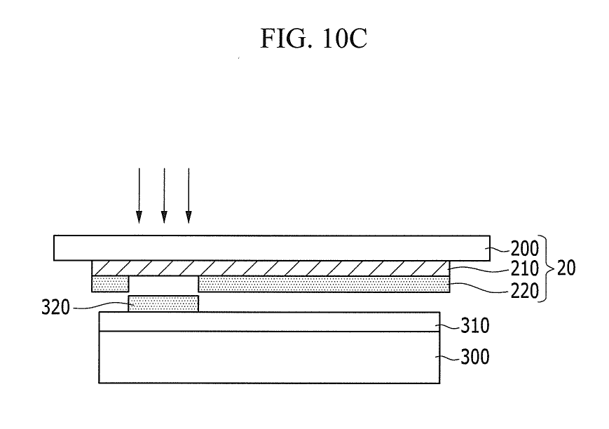

FIG. 10A to FIG. 10C show a process for manufacturing an organic light emitting diode (OLED) display by using a donor substrate that is manufactured by a device and method for manufacturing a donor substrate according to one or more exemplary embodiments of the present invention.

As shown in FIG. 10A, an acceptor substrate 300, on which a pixel electrode layer 310 is formed, is provided. In the present embodiment, a thin film transistor, a planarization layer, and a pixel electrode layer 310 are sequentially stacked on the acceptor substrate 300.

As shown in FIG. 10B, the base film 210 is fixed by the support frame 200 of the donor substrate 20, and the light-to-heat conversion layer 210 and the transfer layer 220 are sequentially stacked. The transfer layer 220 of the donor substrate 20 is located to contact the pixel electrode layer 310 formed on the acceptor substrate 300.

As shown in FIG. 10C, laser beams are irradiated to an area of the donor substrate 20, are absorbed into the light-to-heat conversion layer 210 of the donor substrate 20 to generate heat, which reduces adherence of the transfer layer 220 and the light-to-heat conversion layer 210 thereby causing the transfer layer 220 to transfer to the acceptor substrate 300. As a result, a transfer layer pattern 320 is formed on the pixel electrode layer 310 of the acceptor substrate 300. The transfer process can be performed in an N₂ atmosphere or in a vacuous condition (e.g., to avoid moisture and oxygen in the air, which may degrade the transfer layer pattern 320 made of an organic material).

The organic film pattern 320 during the transfer process can be a single layer or multiple layers selected from the emission layer, the hole injection layer (HIL), the hole transport layer, the electron transfer layer, and the electron injection layer (EIL).

After the transfer process is performed, a cathode is formed on the organic film pattern.

While this disclosure has been described in connection with what is presently considered to be practical exemplary embodiments of the present invention, it is to be understood that the invention is not limited to the disclosed embodiments, but, on the contrary, is intended to cover various modifications and equivalent arrangements included within the spirit and scope of the appended claims, and their equivalents.

What is claimed is:

1. A device for manufacturing a donor substrate, the device comprising:
a film supply unit for supplying a flexible base film in a supply direction;
a film guide unit at a front of the film supply unit in the supply direction for supporting the base film and for guiding the base film in the supply direction;
a frame transferring unit at the front of the supply direction and for providing a support frame configured to be coupled to the base film and for transferring the frame while contacting a first side of the base film; and
a heating unit facing the frame transferring unit with the base film therebetween for heating and for pressurizing a part of the base film contacting the support frame.

2. The device of claim 1, wherein the heating unit has a shape that corresponds to the support frame.

3. The device of claim 2, wherein the heating unit is movable to contact a second side of the base film.

4. The device of claim 1, wherein the film supply unit comprises a roller and is configured to unwind the base film wound on the roller.

5. The device of claim 1, further comprising an extension tray at the front of the film supply unit in the supply direction, and for contacting the first side of the base film and for stretching the base film in a stretching direction.

6. The device of claim 1, further comprising a supplementary guide unit at the front of the film supply unit in the supply direction and for supporting the base film in a crossing direction crossing the supply direction.

7. The device of claim 6, wherein the supplementary guide unit is movable in the crossing direction.

8. A method for manufacturing a donor substrate, the method comprising:
supplying a flexible base film in a supply direction;
contacting a first side of the base film with a support frame for supporting the base film; and
heating a part of the base film contacting the support frame to adhere the support frame to the base film.

9. The method of claim 8, wherein the adhering of the support frame to the base film comprises heating a second side of the base film.

10. The method of claim 9, wherein the heating of the part of the base film contacting the support frame comprises providing a heating unit having a shape that corresponds to the support frame.

11. The method of claim 8, wherein the supplying of the base film in the supply direction comprises extending the base film in the supply direction.

12. The method of claim 8, wherein the supplying of the base film in the supply direction comprises extending the base film in a crossing direction crossing the supply direction.

13. The method of claim 8, wherein the supplying of the base film in the supply direction comprises unwinding the base film, and continuously supplying the base film in the supply direction, the supply direction being a direction in which the base film is unwound.

14. The method of claim 13, further comprising separating an area of the base film to which the support frame is attached from the supplied base film by cutting the base film after the attaching of the support frame to the base film.

15. The method of claim 8, further comprising extending the base film in a stretching direction crossing the supply direction, before the contacting the first side of the base film with the support frame.
